(19) United States
(12) Patent Application Publication
(10) Pub. No.: US 2009/0128429 A1
(43) Pub. Date: May 21, 2009

(54) METHOD OF INHIBITING CROSS-POLARIZATION OF MICROSTRIP ANTENNA AND A DEVICE THEREOF

(75) Inventor: Jr-Ren JENG, Taipei (TW)

Correspondence Address: Workman Nydegger;1000 Eagle Gate Tower, 60 East South Temple, Salt Lake City, UT, 84111, US

(73) Assignee: SMARTANT TELECOM CO., LTD., Jhudong Township (TW)

(21) Appl. No.: 11/941,182

(22) Filed: Nov. 16, 2007

(51) Int. Cl. G01R 29/08

(52) U.S. Cl. 343/703

(57) ABSTRACT

A method of inhibiting cross-polarization of a microstrip antenna and a device thereof. Increase of a microstrip antenna array not only increases co-polarization, but also increases cross-polarization. When the microstrip antenna is designed and fabricated, the fabricated antenna is tested first. That is, intensity distribution of the cross-polarization in a radiation frequency band is tested first, and a radiation frequency that the cross-polarization is corresponding change with is found out when an antenna radiation unit is broken. A slot is fabricated in the corresponding antenna radiation unit to break the symmetry of the antenna radiation unit, so as to effectively inhibit the cross-polarization without influencing the co-polarization of the antenna radiation unit at a corresponding radiation frequency.

### BACKGROUND OF THE INVENTION

1. Field of Invention

The present invention relates to a method of inhibiting cross-polarization of a microstrip antenna and a device thereof, and more particularly to a method of inhibiting cross-polarization by fabricating a slot on a microstrip antenna and a device thereof to break symmetry thereof.

2. Related Art

With the progress of wireless communication technology, new communication products and technology have been developed. The progress of the technology enables the products to become light, thin, small, and short. Hence, the size antennae for receiving or transmitting signals in the communication products decides whether the products can become light, thin, small, and short or not. Among various technologies, the microstrip antenna technology is the most rapidly developing one in the antenna field. The microstrip antennae have advantages of small size, low weight, flexibility, and convenient combination with other elements and circuits.

In a normal microstrip antenna design, the method of coupling power into antenna radiation units is roughly classified into direct-feed mode and indirect-feed mode. Typically, the direct-feed mode uses a coaxial cable or a microstrip line to connect a signal transmission line and the antenna radiation units, so the basic characteristics of the antenna is related much to the position of feed points. In another aspect, the indirect-feed mode provides more space for the combination of a feeding network and a related microwave circuit without breaking the structure of an antenna radiation element. Moreover, the increase of the antenna radiation units on the antenna radiation element not only increases the co-polarization, but also has increased influence on the cross-polarization as well.

Therefore, it has become a problem for researchers to provide a microstrip antenna that inhibits the cross-polarization.

### SUMMARY OF THE INVENTION

Accordingly, the present invention is directed to provide a method of inhibiting cross-polarization of a microstrip antenna and a device thereof. The method inhibits the cross-polarization by fabricating a slot in a microstrip antenna and a device thereof to break symmetry thereof.

The present invention is directed to provide a method of inhibiting cross-polarization of a microstrip antenna, including a microstrip antenna having a plurality of antenna radiation units for testing; the microstrip antenna is detected the intensity distribution of cross-polarization in a radiation frequency band for obtaining the relation of the area of the antenna radiation unit to the radiation frequency that is corresponding to the antenna radiation unit; the symmetry of any one of the antenna radiation units on the microstrip antenna are broken, so as to test a radiation frequency segment in which the cross-polarization is inhibited when the symmetry of the antenna radiation unit is broken in the radiation frequency band; a radiation frequency segment in which the cross-polarization is determined to be inhibited, and a slot is formed in the antenna radiation unit corresponding to the radiation frequency segment.

The method of inhibiting cross-polarization of the microstrip antenna, wherein an area of the antenna radiation unit is inversely proportional to a corresponding radiation frequency, and the slot is fabricated by using a lithography process. The plurality of antenna radiation units is arranged in an array on the microstrip antenna.

The method of inhibiting cross-polarization of the microstrip antenna is used to lies in effectively inhibiting the cross-polarization without influencing co-polarization of the radiation frequency corresponding to the antenna radiation unit.

The present invention is directed to provide another method of inhibiting cross-polarization of a microstrip antenna, including a model of a pre-fabricated microstrip antenna having a plurality of antenna radiation units is established with a simulation software; the relevant parameters including a frequency of a feed signal and impedance of a feeding network are inputted into the simulation software; a radiation field type of the microstrip antenna is simulated with the simulation software, so as to obtain intensity distribution of the cross-polarization in a radiation frequency band of the microstrip antenna, for obtaining the relation of the area of the antenna radiation unit to the radiation frequency that is corresponding to the antenna radiation unit; the symmetry of any one of the antenna radiation units on the microstrip antenna that is broken is tested with the simulation software, so as to test a radiation frequency segment in which the cross-polarization is inhibited when the symmetry of the antenna radiation unit is broken in the radiation frequency band; a radiation frequency segment in which the cross-polarization is determined to be inhibited, a slot is fabricated in the antenna radiation unit corresponding to the radiation frequency segment in the simulation software, and a radiation field type of the microstrip antenna is simulated with the simulation software, so as to make comparison to determine whether the cross-polarization of a radiation frequency corresponding to the antenna radiation unit is inhibited or not.

The method of inhibiting cross-polarization of the microstrip antenna, wherein an area of the antenna radiation unit is inversely proportional to a corresponding radiation frequency. The plurality of antenna radiation units is arranged in an array on the microstrip antenna.

A microstrip antenna, for inhibiting cross-polarization, comprising a substrate, a plurality of antenna radiation units, disposed on the substrate, for receiving and transmitting a radio signal through resonance, a metal circuit, disposed on the substrate, and connected with the plurality of antenna radiation units, a signal feed portion, disposed on the metal circuit, for feeding in a signal current to the metal circuit, and receiving a signal current fed out from the metal circuit, and a slot, formed on one of the plurality of antenna radiation units, for inhibiting cross-polarization of a radiation frequency corresponding to the antenna radiation unit.

The plurality of antenna radiation units is arranged in an array on the substrate.

As for features and examples of the present invention, preferred embodiments will be illustrated in detail with reference to the accompanying drawings.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and thus are not limitative of the present invention, and wherein:

FIG. 1 is a flow chart of the process of inhibiting the cross-polarization of a microstrip antenna of the present invention;

FIG. 2 is a flow chart of another process of inhibiting the cross-polarization of a microstrip antenna of the present invention;

FIG. 3 is a schematic view of a microstrip antenna of the present invention in which the cross-polarization is not inhibited;

FIG. 4 is a schematic view of a microstrip antenna of the present invention in which the cross-polarization is inhibited;

FIG. 5A is a diagram showing horizontal cross-polarization gain of the microstrip antenna in which the cross-polarization is not inhibited measured at the frequency of 3.7 GHz;

FIG. 5B is a diagram showing horizontal cross-polarization gain of the microstrip antenna in which the cross-polarization is not inhibited measured at the frequency of 3.8 GHz;

FIG. 5C is a diagram showing horizontal cross-polarization gain of the microstrip antenna of the present invention in which the cross-polarization is inhibited measured at the frequency of 3.7 GHz; and

FIG. 5D is a diagram showing horizontal cross-polarization gain of the microstrip antenna of the present invention in which the cross-polarization is inhibited measured at the frequency of 3.8 GHz.

### DETAILED DESCRIPTION OF THE INVENTION

The features and examples of the present invention are illustrated in detail below with reference to the accompanying drawings.

The microstrip antenna of the present invention includes, but is not limited to, using the shape, number, and arrangement positions provided in the embodiment. The accompanying drawings are only for reference and illustrative purposes, but are not used to limit the present invention.

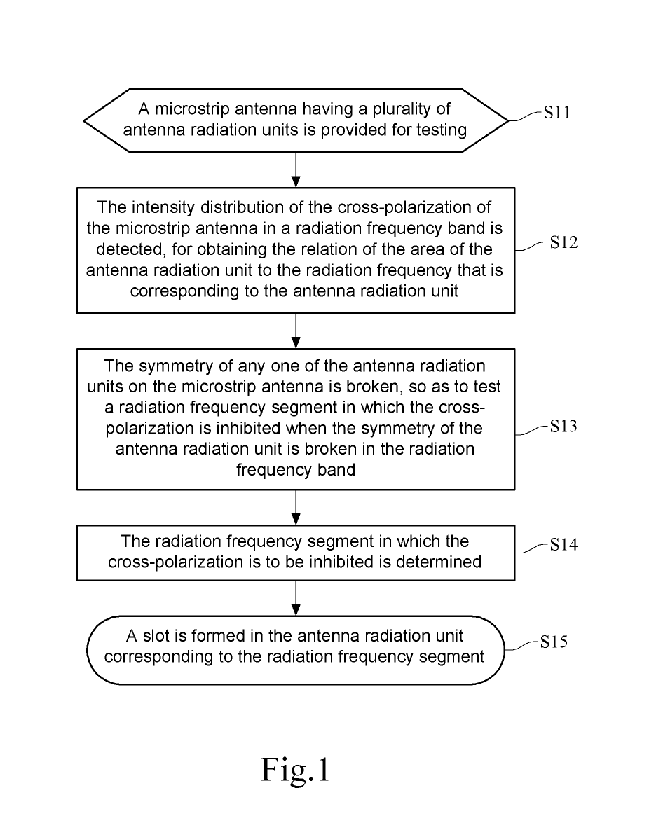

FIG. 1 is a flow chart of the process of inhibiting the cross-polarization of a microstrip antenna of the present invention. The process is described as follows. A microstrip antenna having a plurality of antenna radiation units is provided for testing (step S11). The intensity distribution of the cross-polarization of the microstrip antenna in a radiation frequency band is detected, for obtaining the relation of the area of the antenna radiation unit to the radiation frequency that is corresponding to the antenna radiation unit (step S12). This step is performed for detecting which frequency segment is most seriously affected by the cross-polarization. Then, the symmetry of any one of the antenna radiation units on the microstrip antenna is broken, so as to test a radiation frequency segment in which the cross-polarization is inhibited when the symmetry of the antenna radiation unit is broken in the radiation frequency band (step S13). Thus, the radiation frequency segment corresponding to any one of the antenna radiation units on the microstrip antenna in the radiation frequency band is obtained. As each antenna radiation unit contributes different signal intensity for each frequency segment, any one of the radiation units of the antenna has different influence on the cross-polarization. Therefore, in order to improve the influence of cross-polarization on a certain radiation frequency segment, the antenna radiation unit corresponding to the frequency segment must be found out first. Then, the radiation frequency segment in which the cross-polarization is to be inhibited is determined (step S14). Next, a slot is formed in the antenna radiation unit corresponding to the radiation frequency segment (step S15). As the symmetry of current flowing in the antenna radiation unit is broken after the slot is formed in the antenna radiation unit, the cross-polarization in the corresponding frequency segment is inhibited.

The method of inhibiting cross-polarization of the microstrip antenna, wherein an area of the antenna radiation unit is inversely proportional to a corresponding radiation frequency, and the slot is fabricated by using a lithography process. The slot is formed by a lithography process. The plurality of antenna radiation units is arranged in an array on the microstrip antenna.

When the method of inhibiting cross-polarization of a microstrip antenna is designed and applied, the microstrip antenna must be tested. The testing is performed by using an anechoic chamber, in which metal walls are used to isolate the interference of external signals, and an electromagnetic wave absorption material is attached on the walls from inside to reduce the reflected energy in the chamber. In the test, the distribution of parameters (e.g., amplitudes and phases) of the electromagnetic waves radiated by an antenna under test (AUT) in a near field space is detected by a scanning probe (during the test in embodiments of the present invention, the distance between the AUT and the scanning probe is 4 m). The scanning mode may be planar, cylindrical, or spherical. The RF (or microwave) signals are transmitted to a vector network analyzer (VNA) through a coaxial cable, so as to obtain relevant data. Then, the data are processed with methods such as probe radiation field type correction and numerical Fourier transformation in the background, so as to obtain the desired radiation (far field) field type of the AUT.

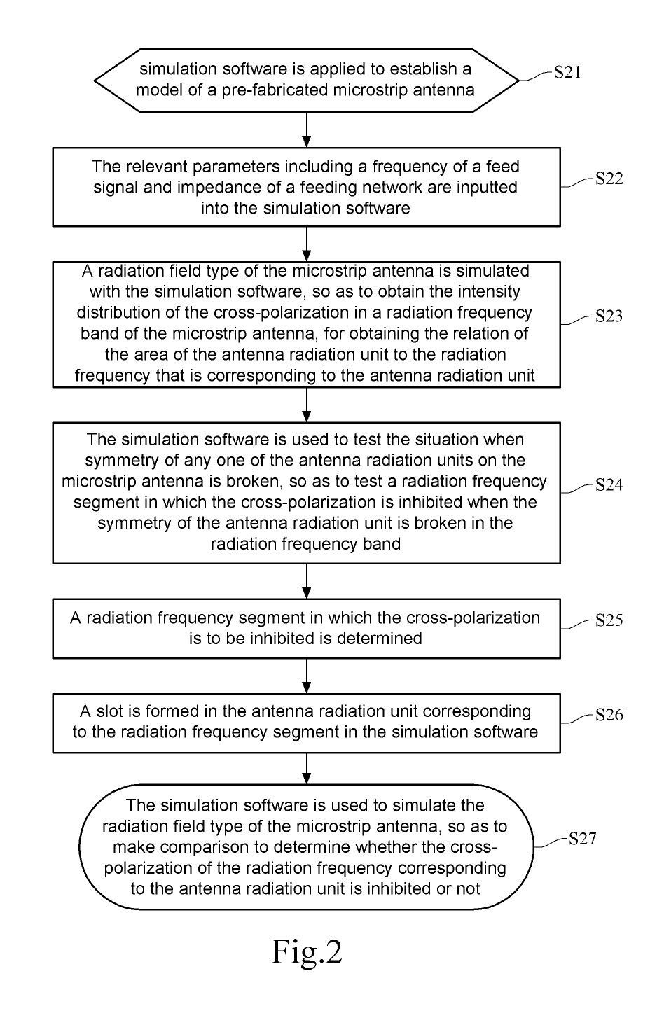

FIG. 2 is a flow chart of another process of inhibiting cross-polarization of a microstrip antenna of the present invention. The process is described as follows. Firstly, when the method of inhibiting cross-polarization of a microstrip antenna is designed and applied, simulation software is applied to establish a model of a pre-fabricated microstrip antenna (step S21). Next, relevant parameters including a frequency of a feed signal and impedance of a feeding network are inputted into the simulation software (step S22). Then, a radiation field type of the microstrip antenna is simulated with the simulation software, so as to obtain the intensity distribution of the cross-polarization in a radiation frequency band of the microstrip antenna, for obtaining the relation of the area of the antenna radiation unit to the radiation frequency that is corresponding to the antenna radiation unit (step S23). Then, the simulation software is used to test the situation when symmetry of any one of the antenna radiation units on the microstrip antenna is broken, so as to test a radiation frequency segment in which the cross-polarization is inhibited when the symmetry of the antenna radiation unit is broken in the radiation frequency band (step S24). Next, a radiation frequency segment in which the cross-polarization is to be inhibited is determined (step S25). Next, a slot is formed in the antenna radiation unit corresponding to the radiation frequency segment in the simulation software (step S26). Then, the simulation software is used to simulate the radiation field type of the microstrip antenna, so as to make comparison to determine whether the cross-polarization of the radiation frequency corresponding to the antenna radiation unit is inhibited or not.

The method of inhibiting cross-polarization of the microstrip antenna, wherein an area of the antenna radiation unit is inversely proportional to a corresponding radiation frequency, and the slot is fabricated by using a lithography process. The plurality of antenna radiation units is arranged in an array on the microstrip antenna.

Then, a final product is fabricated according to the simulation results and is tested. The testing is performed by using an anechoic chamber, in which metal walls are used to isolate the interference of external signals, and an electromagnetic wave absorption material is attached on the walls from inside to reduce the reflected energy in the chamber. In the test, the distribution of parameters (e.g., amplitudes and phases) of the electromagnetic waves radiated by an antenna under test (AUT) in a near field space is detected by a scanning probe (during the test in embodiments of the present invention, the distance between the AUT and the scanning probe is 4 m). The scanning mode may be planar, cylindrical, or spherical. The RF (or microwave) signals are transmitted to a vector network analyzer (VNA) through a coaxial cable, so as to obtain relevant data. Then, the data are processed with methods such as probe radiation field type correction and numerical Fourier transformation in the background, so as to obtain the desired radiation (far field) field type of the AUT.

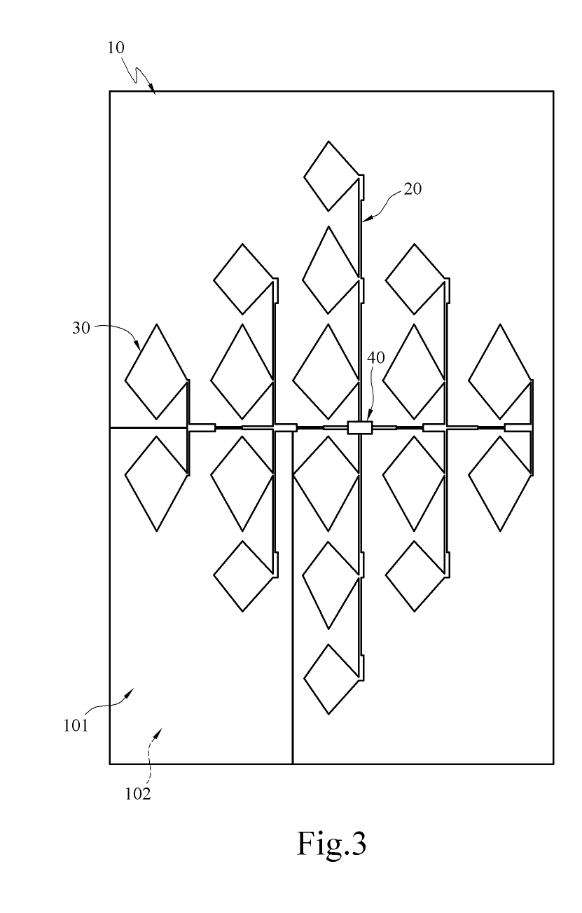

FIG. 3 is a schematic view of a microstrip antenna of the present invention in which the cross-polarization is not inhibited. Referring to FIG. 3, the microstrip antenna includes a substrate 10, a metal circuit 20, a plurality of antenna radiation units 30, and a signal feed portion 40. The substrate 10 has a first surface 101 and a second surface 102 opposite to the first surface 101. The metal circuit 20 is formed on the first surface 101. A plurality of antenna radiation units 30 is disposed on the first surface 101, for receiving and transmitting a radio signal through resonance. The metal circuit 20 is disposed on the first surface 101, and is connected with the plurality of antenna radiation units 30.

The plurality of antenna radiation units 30 is arranged in an array on the substrate.

The substrate 10 normally is a PCB. Certainly, other types of substrates are also applicable, and the substrate 10 can be a hard board or a flexible soft board. A material of the hard board is glass fiber, Bakelite or other materials, and a material of the flexible soft board is polyimide (PI), polyethylene terephthalate (PET), or other materials.

The metal circuit 20 receives a feed signal from the signal feed portion 40, and transmits the feed signal to a plurality of corresponding antenna radiation units 30.

The plurality of antenna radiation units 30 converts the feed signal transmitted from the metal circuit 20 to a radiation signal.

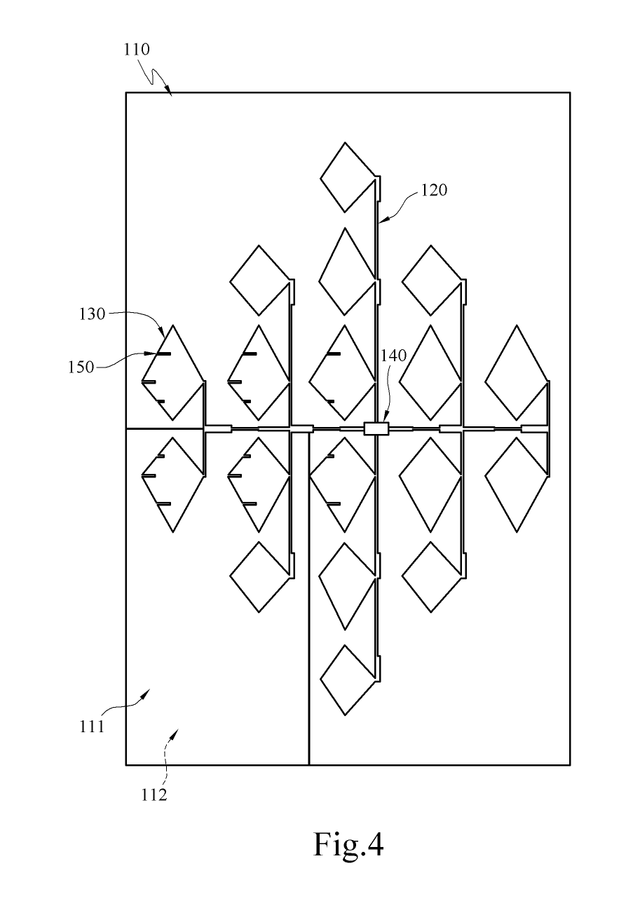

FIG. 4 is a schematic view of a microstrip antenna of the present invention in which the cross-polarization is inhibited. Referring to FIG. 4, the microstrip antenna includes a substrate 110, a metal circuit 120, a plurality of antenna radiation units 130, a signal feed portion 140, and a slot 150. The substrate 110 has a first surface 111 and a second surface 112 opposite to the first surface 111. The metal circuit 120 is formed on the first surface 111. A plurality of antenna radiation units is formed on the first surface 111, and is arranged in an array. The metal circuit 120 is disposed on the first surface 111, and is connected with the plurality of antenna radiation units 130.

The substrate 110 normally is a PCB. Certainly, other types of substrates are also applicable, and the substrate 110 can be a hard board or a flexible soft board. A material of the hard board is glass fiber, Bakelite or other materials, and a material of the flexible soft board is polyimide (PI), polyethylene terephthalate (PET), or other materials.

The metal circuit 120 receives a feed signal from the signal feed portion 140, and transmits the feed signal to a plurality of corresponding antenna radiation units 130.

The plurality of antenna radiation units 130 receives the feed signal transmitted from the metal circuit 120, and converts it to a radio signal.

The slot 150 is formed in the first surface 111, for breaking symmetry of the current flowing in the antenna radiation units 130, so as to inhibit the cross-polarization. The shape of the slot 150 may be, but is not limited to, a rectangle, square, and round. The slot 150 is formed by using a lithography process.

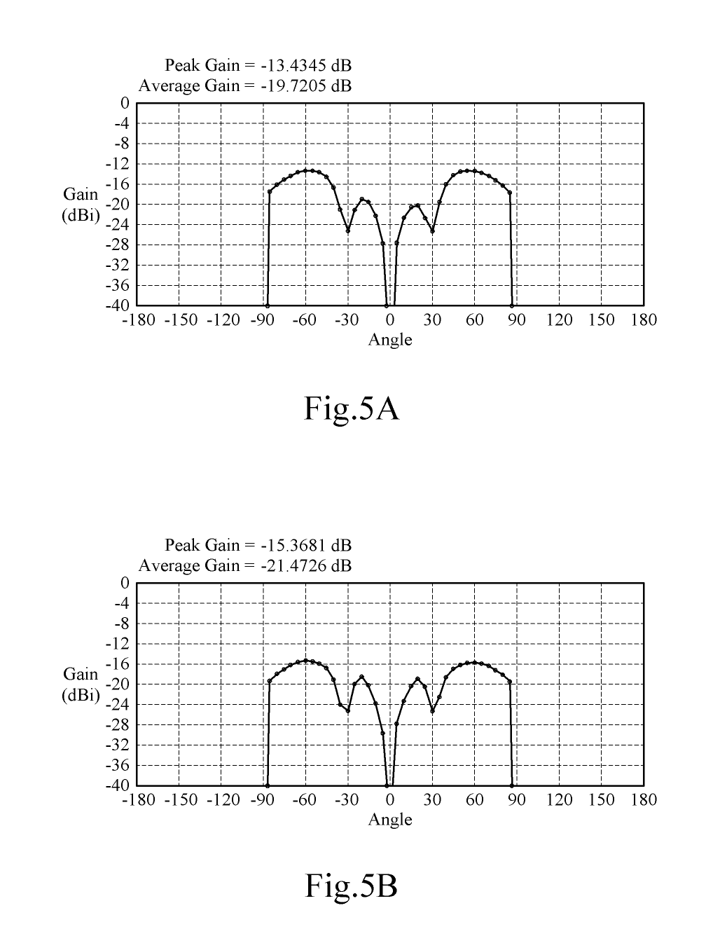

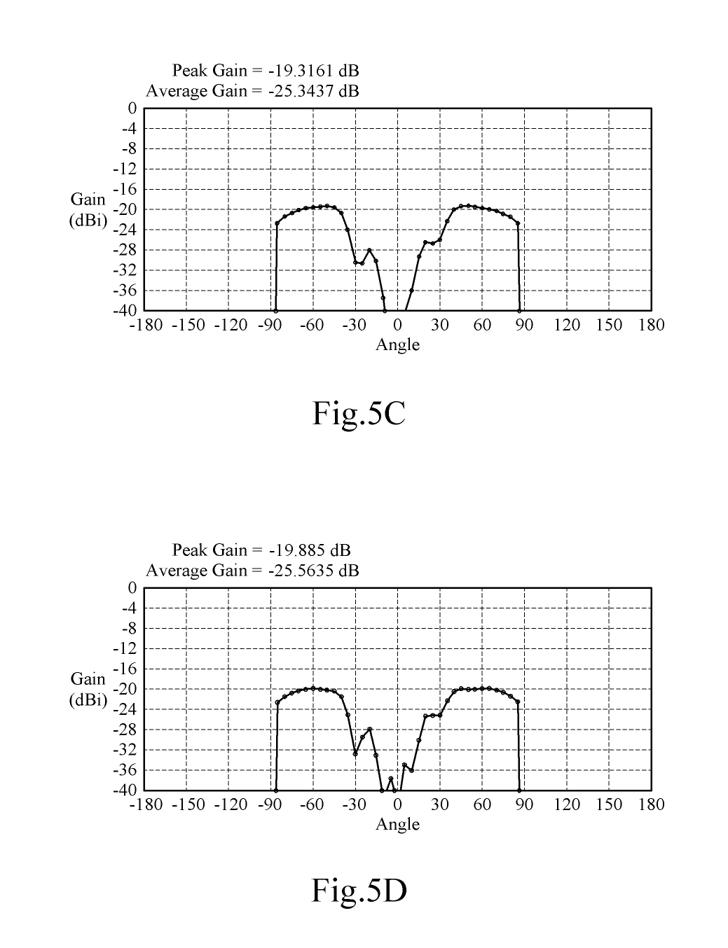

FIGS. 5A and 5B are diagrams showing horizontal cross-polarization gain of the microstrip antenna in which the cross-polarization is not inhibited measured at the frequencies of 3.7 GHz and 3.8 GHz respectively. FIGS. 5C and 5D are diagrams showing horizontal cross-polarization gain of the microstrip antenna of the present invention in which the cross-polarization is inhibited measured at the frequencies of 3.7 GHz and 3.8 GHz respectively. Referring to FIGS. 5A, 5B, 5C, and 5D, it is known that after the slot is formed in the antenna radiation unit, the gain of horizontal cross-polarization is obviously reduced by 4-6 dB in average at the frequencies of 3.7 GHz and 3.8 GHz respectively.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method of inhibiting cross-polarization of a microstrip antenna, comprising:
providing a microstrip antenna for testing, wherein the microstrip antenna has a plurality of antenna radiation units;
detecting intensity distribution of cross-polarization of the microstrip antenna in a radiation frequency band, for obtaining the relation of the area of the antenna radiation unit to the radiation frequency that is corresponding to the antenna radiation unit;
breaking symmetry of any one of the antenna radiation units on the microstrip antenna, so as to test a radiation frequency segment in which the cross-polarization is inhibited when the symmetry of the antenna radiation unit is broken in the radiation frequency band;
determining a radiation frequency segment in which the cross-polarization is to be inhibited; and
forming a slot in the antenna radiation unit corresponding to the radiation frequency segment.

2. The method of inhibiting cross-polarization of a microstrip antenna as claimed in claim 1, wherein an area of the antenna radiation unit is inversely proportional to the corresponding radiation frequency.

3. The method of inhibiting cross-polarization of a microstrip antenna as claimed in claim 1, wherein the slot is fabricated by using a lithography process.

4. The method of inhibiting cross-polarization of a microstrip antenna as claimed in claim 1, wherein the plurality of antenna radiation units is arranged in an array.

5. A method of inhibiting cross-polarization of a microstrip antenna, comprising:
establishing a model of a pre-fabricated microstrip antenna with a simulation software, wherein the microstrip antenna has a plurality of antenna radiation units;
inputting relevant parameters including a frequency of a feed signal and impedance of a feeding network into the simulation software;
simulating a radiation field type of the microstrip antenna with the simulation software, so as to obtain intensity distribution of the cross-polarization in a radiation frequency band of the microstrip antenna, for obtaining the relation of the area of the antenna radiation unit to the radiation frequency that is corresponding to the antenna radiation unit;
testing a situation when symmetry of any one of the antenna radiation units on the microstrip antenna is broken with the simulation software, so as to test a radiation frequency segment in which the cross-polarization is inhibited when the symmetry of the antenna radiation unit is broken in the radiation frequency band;
determining a radiation frequency segment in which the cross-polarization is to be inhibited;
fabricating a slot in the antenna radiation unit corresponding to the radiation frequency segment in the simulation software; and
simulating a radiation field type of the microstrip antenna with the simulation software, so as to make comparison to determine whether the cross-polarization of a radiation frequency corresponding to the antenna radiation unit is inhibited or not.

6. The method of inhibiting cross-polarization of a microstrip antenna as claimed in claim 5, wherein an area of the antenna radiation unit is inversely proportional to a corresponding radiation frequency.

7. A microstrip antenna, for inhibiting cross-polarization, comprising:
a substrate;
a plurality of antenna radiation units, disposed on the substrate, for receiving and transmitting a radio signal through resonance;
a metal circuit, disposed on the substrate, and connected with the plurality of antenna radiation units;
a signal feed portion, disposed on the metal circuit, for feeding in a signal current to the metal circuit, and receiving a signal current fed out from the metal circuit; and
a slot, formed on one of the plurality of antenna radiation units, for inhibiting cross-polarization of a radiation frequency corresponding to the antenna radiation unit.

8. The microstrip antenna as claimed in claim 7, wherein the plurality of antenna radiation units is arranged in an array.
